(19) United States
(12) Patent Application Publication
(10) Pub. No.: US 2009/0151635 A1
(43) Pub. Date: Jun. 18, 2009

(54) Adaptively Coupled Plasma Source Having Uniform Magnetic Field Distribution and Plasma Chamber Having the Same

(76) Inventor: Nam Hun Kim, Gyeonggi-do (KR)

Correspondence Address: MORGAN & FINNEGAN Transition Team;C/O Locke Lord Bissell & Liddell, 3 WORLD FINANCIAL CENTER, NEW YORK, NY, 10281-2101, US

(21) Appl. No.: 12/090,928

(22) PCT Filed: Oct. 20, 2006
(86) PCT No.: PCT/KR06/04276

§ 371 Date: Aug. 28, 2008

(30) Foreign Application Priority Data
Oct. 21, 2005 (KR) 10-2005-0099804

(51) Int. Cl. C23C 16/505

(52) U.S. Cl. 118/723 E; 118/723 R

(57) ABSTRACT

Disclosed is an adaptively coupled plasma source having a uniform magnetic field distribution. The adaptively coupled plasma source includes a flat plate shaped bushing disposed above a reaction chamber in a center region of the reaction chamber, a plurality of upper coils extended from the bushing to be disposed above the reaction chamber, so as to spirally surround the bushing, and a plurality of side coils arranged around a sidewall portion of the reaction chamber to surround the reaction chamber.

### TECHNICAL FIELD

The present invention relates to semiconductor fabrication facilities, and more particularly, to an adaptively coupled plasma (ACP) source having a uniform magnetic field distribution and a method for processing a semiconductor wafer using the ACP source.

### BACKGROUND ART

In general, an etching process, more particularly, a dry etching process is a process for removing a film formed on a semiconductor wafer by use of plasma on the basis of the pattern of a photoresist film or hard mask that is also formed on the semiconductor wafer above the film to be removed. To perform the above described dry etching process, plasma has to be first produced in a reaction chamber. A plasma producing source may be classified into an inductively coupled plasma (ICP) source and a capacitively coupled plasma (CCP) source.

The use of the CCP source has advantages of high process replicability and high etching selectivity against a photoresist film, but suffers from the production of low density plasma and consequently, enormous consumption of electricity. On the other hand, although the use of the ICP source is advantageous to achieve high density plasma and reduced consumption of electricity while enabling independent control of plasma density and ion energy, it has disadvantages of low selectivity against to a photoresist film and low process replicability. Further, the ICP source may cause aluminum contamination when it uses an alumina dome. Consequently, the CCP source and the ICP source have conflicting advantages and disadvantages, so there is a problem in that an etching rate should be sacrificed to obtain a desired selectivity and conversely, the selectivity should be sacrificed to obtain a desired etching rate. For this reason, there has been recently proposed an adaptively coupled plasma (ACP) source capable of providing only advantages of both the CCP source and the ICP source.

FIG. 1 is a sectional view illustrating an ACP source and a plasma chamber having the ACP source according to an embodiment of the prior art. FIG. 2 is a plan view of the ACP source shown in FIG. 1. FIG. 3 is a graph illustrating the distribution of a magnetic field in the plasma chamber of FIG. 1.

Referring first to FIGS. 1 and 2, the plasma chamber 200 having the ACP source 100 includes a chamber shell 210 defining an interior space of the chamber 200 for producing plasma 400 therein. A wafer support 220 is disposed in the interior space of the chamber 200 in a lower region of the space and adapted to support a wafer 300 thereon. The ACP source 100 is disposed on an upper surface of the chamber shell 210. The ACP source 100 includes a flat plate shaped bushing 110 located at the center thereof and unit coils 120 extended from the bushing 110 to spirally surround the bushing 110. The flat plate shaped water support 220 is connected to a lower radio frequency (RF) power source 230, and the bushing 110 is connected to an upper RF power source 240.

The ACP source 100 having the above described configuration shows advantages of the CCP source by the lower side flat plate shaped wafer support 220 and the upper side bushing 110 as well as advantages of the ICP source by the unit coils 120.

However, the above described conventional ACP source 100 has a problem in that the distribution of a magnetic field in the plasma chamber 200 may be irregular as shown in FIG. 3. Specifically, the magnetic field in the plasma chamber 200 has a relatively high strength at a center region of the wafer 300, whereas has a relatively low strength at an border region of the wafer 300. The irregular strength distribution of the magnetic field may cause irregular density of the plasma 400, thus resulting in irregular process results.

### DISCLOSURE

### Technical Problem

Therefore, the present invention has been made in view of the above problems, and it is an object of the present invention to provide an adaptively coupled plasma (ACP) source capable of achieving a uniform strength distribution of a magnetic field in a chamber.

It is another object of the present invention to provide a plasma chamber having an ACP source that is capable of achieving a uniform strength distribution of a magnetic field in a reaction chamber.

### Technical Solution

In accordance with an aspect of the present invention, the above and other objects can be accomplished by the provision of an adaptively coupled plasma source comprising: a flat plate shaped bushing disposed above a reaction chamber in a center region of the reaction chamber; a plurality of upper coils extended from the bushing to be disposed above the reaction chamber, so as to spirally surround the bushing; and a plurality of side coils arranged around a sidewall portion of the reaction chamber to surround a periphery of the reaction chamber.

In accordance with another aspect of the present invention, there is provided a plasma chamber comprising: a chamber shell defining a reaction space for producing plasma therein; a flat plate shaped wafer support disposed in a lower region of the reaction space and adapted to support a wafer thereon; a lower radio frequency power source connected to the flat plate shaped wafer support; an adaptively coupled plasma source including: a flat plate shaped bushing disposed above the chamber shell in a center region of the chamber shell; a plurality of upper coils extended from the bushing to be disposed above the chamber shell, so as to spirally surround the bushing; and a plurality of side coils arranged around a sidewall portion of the chamber shell to surround the chamber shell; and an upper radio frequency power source connected to the bushing.

### ADVANTAGEOUS EFFECTS

In an adaptively coupled plasma (ACP) source and a plasma chamber having the ACP source according to the present invention, side coils are arranged around a sidewall portion of a reaction chamber, so as to achieve a uniform distribution of a magnetic field in the reaction chamber. This has the effect of achieving a uniform density distribution of plasma. Furthermore, by appropriately selecting a power source to be connected to the ACP source and regulating a density of electric current applied to the side coils, the overall density of plasma in the reaction chamber can be further increased.

### DESCRIPTION OF DRAWINGS

The above and other objects, features and other advantages of the present invention will be more clearly understood from the following detailed description taken in conjunction with the accompanying drawings, in which:

FIG. 1 is a sectional view illustrating an adaptively coupled plasma (ACP) source and a plasma chamber having the ACP source according to an embodiment of the prior art;

FIG. 2 is a plan view of the ACP source shown in FIG. 1;

FIG. 3 is a graph illustrating the distribution of a magnetic field in the plasma chamber of FIG. 1;

FIG. 4 is a sectional view illustrating an ACP source and a plasma chamber having the ACP source according to the present invention;

FIG. 5 is a view illustrating side coils constituting the ACP source shown in FIG. 4;

FIG. 6 is a graph illustrating the density distribution of a magnetic flux that is produced in the plasma chamber by the side coils of FIG. 5;

FIG. 7 is a graph illustrating the density distribution of a magnetic flux that is produced in the plasma chamber by the ACP source of FIG. 4; and

FIG. 8 is a graph illustrating a method for regulating the density of a magnetic flux in the plasma chamber having the ACP plasma source according to the present invention.

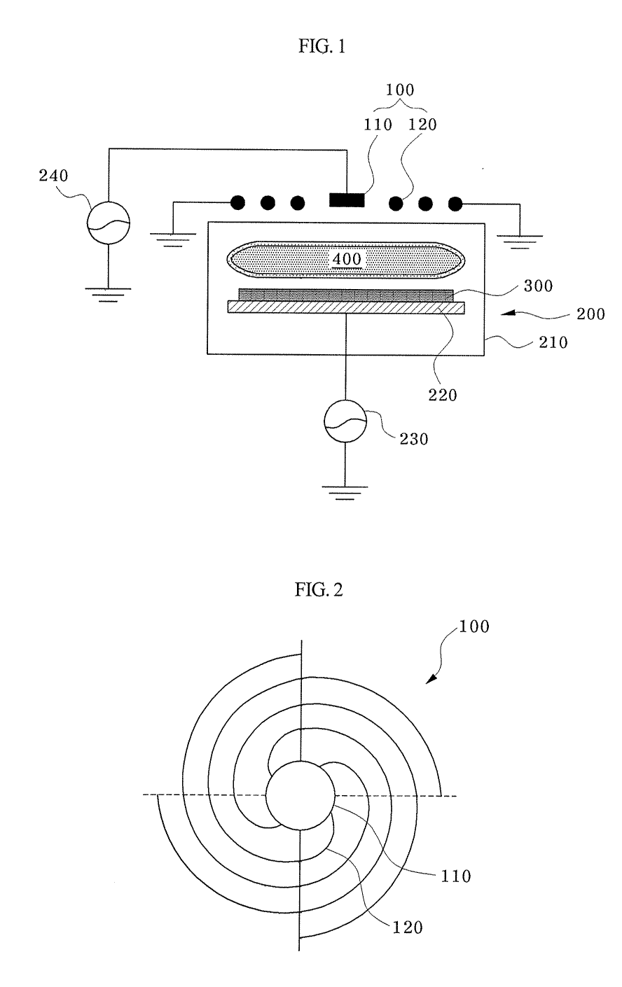

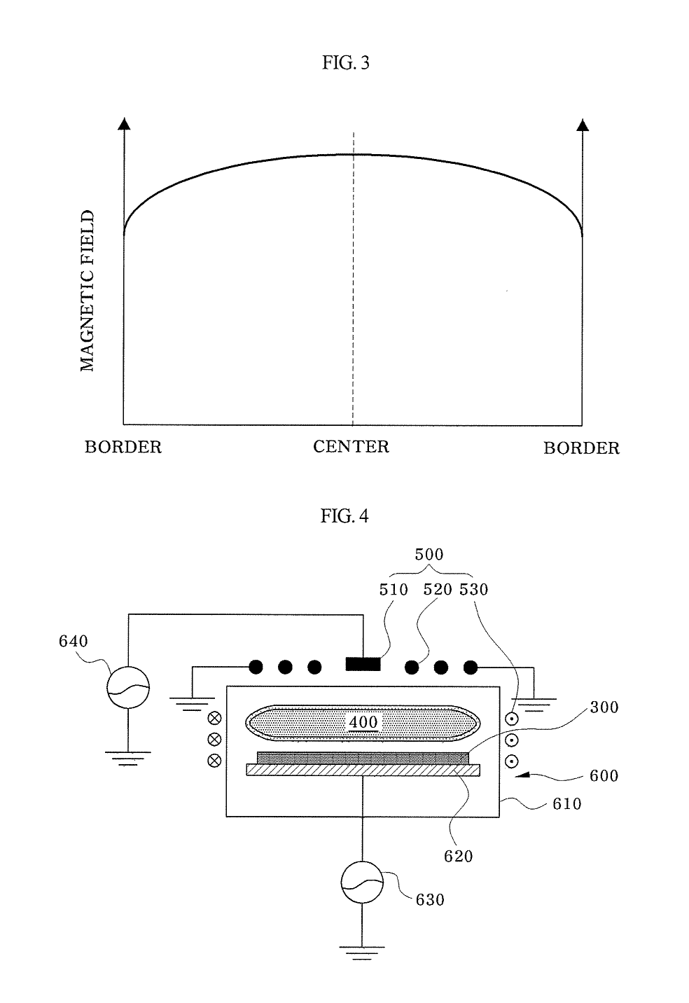

### BEST MODE

An adaptively coupled plasma source according to the present invention has a feature in that it comprises: a flat plate shaped bushing disposed above a reaction chamber in a center region of the reaction chamber; a plurality of upper coils extended from the bushing to be disposed above the reaction chamber, so as to spirally surround the bushing; and a plurality of side coils arranged around a sidewall portion of the reaction chamber to surround a periphery of the reaction chamber.

Preferably, the plurality of side coils are arranged so that they are vertically spaced apart from one another by a predetermined distance.

The side coils may be made of silver, copper, aluminum, gold, or platinum.

A plasma chamber according to the present invention has a feature in that it comprises: a chamber shell defining a reaction space for producing plasma therein; a flat plate shaped wafer support disposed in a lower region of the reaction space and adapted to support a wafer thereon; a lower radio frequency power source connected to the flat plate shaped wafer support; an adaptively coupled plasma source including: a flat plate shaped bushing disposed above the chamber shell in a center region of the chamber shell; a plurality of upper coils extended from the bushing to be disposed above the chamber shell, so as to spirally surround the bushing; and a plurality of side coils arranged around a sidewall portion of the chamber shell to surround the chamber shell; and an upper radio frequency power source connected to the bushing.

Preferably, the plurality of side coils are arranged so that they are vertically spaced apart from one another by a predetermined distance.

The side coils may be made of silver, copper, aluminum, gold, or platinum.

The side coils may be connected to the upper radio frequency power source.

In the present invention, the plasma chamber may further comprise a separate power source connected to the side coils.

### MODE FOR INVENTION

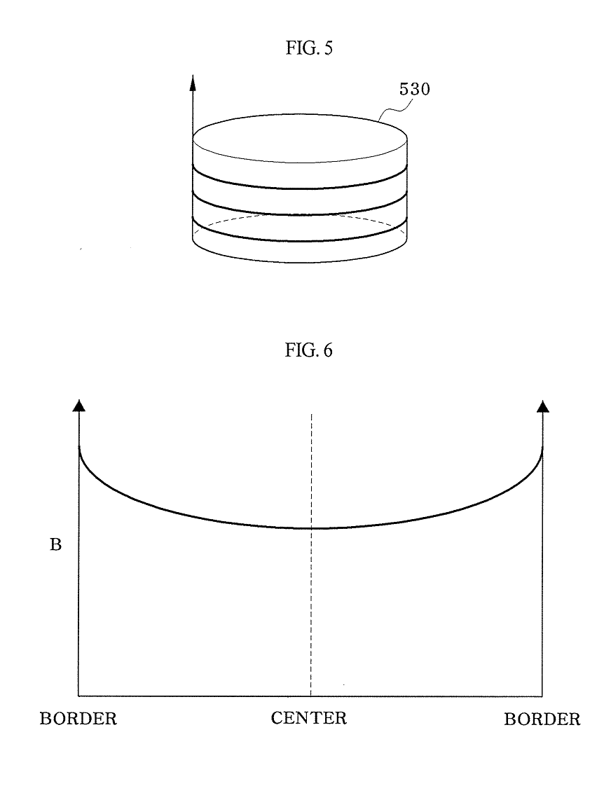

FIG. 4 is a sectional view illustrating an ACP source and a plasma chamber having the ACP source according to the present invention. FIG. 5 is a view illustrating side coils constituting the ACP source shown in FIG. 4.

Referring to FIGS. 4 and 5, the ACP source 500 according to the present invention includes a flat plate shaped bushing 510 that is disposed above a reaction chamber 600 in a center region of the chamber 600, a plurality of upper coils 520 spirally disposed above the reaction chamber 600 to surround the bushing 510, and a plurality of side coils 530 disposed around a sidewall portion of the reaction chamber 600 to surround the reaction chamber 600. The configuration of the upper coils 520 is the same as that described with reference to FIG. 2a and thus, explanation thereof will be omitted herein. The side coils 530 include a plurality of unit coils that are vertically spaced apart from one another by a predetermined distance to surround an outer periphery of the reaction chamber 600.

The plasma chamber according to the present invention includes the ACP source 500, the reaction chamber 600, and power sources 630 and 640. The reaction chamber 600 includes a chamber shell 610 defining a reaction space for producing plasma 400 and a flat plate shaped wafer support 620 disposed in a lower region of the reaction space and adapted to support a wafer 300. The flat plate shaped wafer support 620 is connected to the lower RF power source 630, and the bushing 510 is connected to the upper RF power source 640. With this configuration, if the upper RF power source 640 applies a bias to the bushing 510, the bias is transmitted to the upper coils 520. Although not shown in the drawings, the side coils 530 are also connected to a power source. In this case, the side coils 530 may be connected to the upper RF power source 640 along with the bushing 510, or may be connected to a separate power source (not shown).

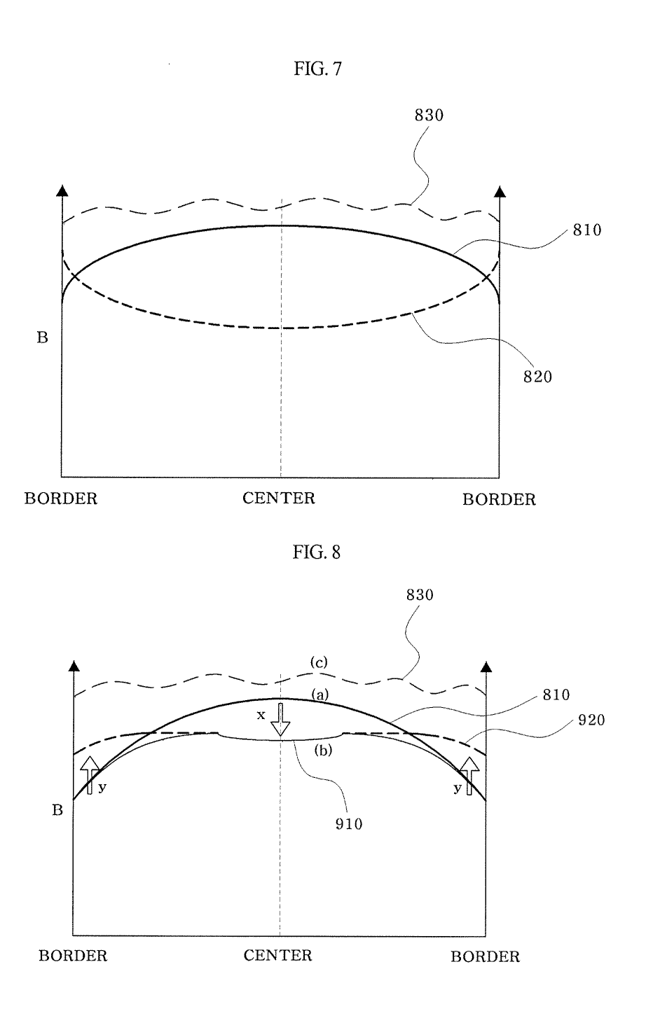

FIG. 6 is a graph illustrating the density distribution of a magnetic flux that is produced in the plasma chamber by the side coils of FIG. 5. FIG. 7 is a graph illustrating the density distribution of a magnetic flux that is produced in the plasma chamber by the ACP source of FIG. 4.

Referring to FIGS. 6 and 7, in the ACP source and the plasma chamber having the ACP source according to the present invention, as a result of arranging the side coils 530 around a sidewall portion of the reaction chamber 600 to surround the reaction chamber 600, the reaction chamber 600 shows a uniform strength distribution of a magnetic field therein. Specifically, as shown in FIG. 6, with the arrangement of the side coils 530 constituting the ACP source 500, the density of a magnetic flux in the reaction chamber 600 is relatively low in a center region of the wafer, whereas is relatively high in an border region of the wafer. The resulting density distribution of the magnetic flux is opposite to the density distribution of a magnetic flux produced by the upper coils 520 of the ACP source 500. Accordingly, as shown in FIG. 7, the reaction chamber 600 has a uniform overall density distribution of a magnetic flux therein. More particularly, the density of the magnetic flux produced in the reaction chamber 600 by the upper coils 520 is lower at the border region of the wafer than the center region of the wafer, as shown by the solid line “810” in the drawings. Conversely, the density of the magnetic flux produced in the reaction chamber 600 by the side coils 530 is lower at the center region of the wafer than the border region of the wafer, as shown by the dotted line “820” in the drawings. In conclusion, the overall density of the magnetic flux in the reaction chamber 600 shows a uniform distribution in both the center region and the border region of the wafer, as shown by the dashed line “830” in the drawings. If the density distribution of the magnetic flux in the reaction chamber 600 is uniform, similarly, the density of plasma produced in the reaction chamber 600 shows a uniform distribution because the density of plasma is proportional to the density of magnetic flux. In addition, by appropriately selecting power sources to be connected to the ACP source and regulating the density of electric current that is applied to the side coils 530, the overall density of plasma in the reaction chamber 600 can be further increased.

FIG. 8 is a graph illustrating a method for regulating the density of the magnetic flux produced in the plasma chamber having the ACP plasma source according to the present invention.

Referring to FIG. 8, the solid line 810 as shown by “(a)” in the drawing is a line showing the distribution of a magnetic flux obtained in the case where a conventional ACP source has only the bushing 510 and the upper coils 520 without having the side coils 530. In this case, to obtain a uniform density distribution of the magnetic flux, the density of a magnetic flux in the center region of the wafer may be reduced as shown by the arrow “x” in the drawing (See the solid line “910” in FIG. 8), or the density of a magnetic flux in the border region of the wafer may be increased as shown by the arrows “y” in the drawing (See the dotted line “920” in FIG. 8). For this, the size of the bushing 510, the distance between the respective upper coils 520 in the border region of the wafer, or the like may be regulated. On the other hand, in the case where the side coils 530 are arranged to surround the reaction chamber 600 as shown by “(c)” in the drawing, the density of a magnetic flux has a uniform distribution in both the center region and the border region of the wafer (See the dashed line “830” in FIG. 8).

In particular, the density distribution of the magnetic flux can be regulated in various manners in consideration of the sectional shape, arrangement structure, diameter, thickness, number of turns, distance, or constituent material of the side coils 530 as well as the kind of the power source connected to the side coils 530. For example, the side coils 530 may have a circular or polygonal cross sectional shape, may have a flat plate shape, or may have a symmetrical or asymmetrical shape about a center axis thereof. When the side coils 530 are symmetrically formed about the center axis thereof, the side coils 530 have a constant diameter through the overall height thereof. On the other hand, when the side coils 530 are asymmetrically formed about the center axis thereof, the respective side coils 530 have different diameters from one another according to their heights. Also, the side coils 530 may have a polygonal shape or wavy shape, may be arranged to partially or completely cover the reaction chamber 600, or may be connected to a DC or AC power source, or other power sources including a pulse generator. Also, the side coils 530 may be made of silver, copper, aluminum, gold, platinum, or the like.

### INDUSTRIAL APPLICABILITY

As apparent from the above description, the present invention is applicable to semiconductors using a plasma chamber and other similar apparatuses and processes in the related fields.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. An adaptively coupled plasma source comprising:
a flat plate shaped bushing disposed above a reaction chamber in a center region of the reaction chamber;
a plurality of upper coils extended from the bushing to be disposed above the reaction chamber, so as to spirally surround the bushing; and
a plurality of side coils arranged around a sidewall portion of the reaction chamber to surround a periphery of the reaction chamber.

2. The adaptively coupled plasma source according to claim 1, wherein the plurality of side coils are arranged so that they are vertically spaced apart from one another by a predetermined distance.

3. The adaptively coupled plasma source according to claim 1, wherein the side coils are made of silver, copper, aluminum, gold, or platinum.

4. A plasma chamber comprising:
a chamber shell defining a reaction space for producing plasma therein;
a flat plate shaped wafer support disposed in a lower region of the reaction space and adapted to support a wafer thereon;
a lower radio frequency power source connected to the flat plate shaped wafer support;
an adaptively coupled plasma source including: a flat plate shaped bushing disposed above the chamber shell in a center region of the chamber shell; a plurality of upper coils extended from the bushing to be disposed above the chamber shell, so as to spirally surround the bushing; and a plurality of side coils arranged around a sidewall portion of the chamber shell to surround the chamber shell; and
an upper radio frequency power source connected to the bushing.

5. The plasma chamber according to claim 4, wherein the plurality of side coils are arranged so that they are vertically spaced apart from one another by a predetermined distance.

6. The plasma chamber according to claim 4, wherein the side coils are made of silver, copper, aluminum, gold, or platinum.

7. The plasma chamber according to claim 4, wherein the side coils are connected to the upper radio frequency power source.

8. The plasma chamber according to claim 4, further comprising:
a separate power source connected to the side coils.
